(19) United States
(12) Patent Application Publication
(10) Pub. No.: US 2004/0025334 A1
(43) Pub. Date: Feb. 12, 2004

(54) Method of securely fastening a shield to a circuit board

(76) Inventors: Ming Wen, Shanghai (CN); Quan-Ding Xu, Taipei Hsien (TW); Su-Tane Yin, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,673

(22) Filed: Aug. 6, 2002

(51) Int. Cl. H05K 3/36

(52) U.S. Cl. 29/832; 29/830

(57) ABSTRACT

A method for fixing an electromagnetic interference (EMI) shield onto a circuit board. The circuit board has a plurality of holes, and the EMI shield has a plurality of fasteners that correspond to the plurality of holes. The method includes inserting the plurality of fasteners into the corresponding plurality of holes of the circuit board so as to fix the EMI shield onto the circuit board.

### BACKGROUND OF INVENTION

1. Field of the Invention

The present invention relates to methods of securely fastening shields, and more particularly, the present invention is a method of securely fastening a shield onto a circuit board.

2. Description of the Prior Art

In recent years, with a rapid expansion of an electronics industry, all kinds of high-precision electronic products have been developed. In order to prevent important components of the electronic products from electromagnetic wave interference (EMI), most devices employ an EMI shield, which covers the important components on the circuit board. The electric field inside the shield is approximately zero, thus the important circuit components are well protected.

Prior art EMI shields can be separated by architecture into two major types: simple and complex. Simple EMI shields are fixed to the circuit board as follows. First, after ensuring that all of the components that will be covered by the shield are operating properly, all of the components are covered with the shield. Then, the shield is welded to the ground of the circuit board, so that the circuit board and the EMI shield are fastened together. An advantage of this method is that the EMI shield and the circuit board are tightly fastened, so the important components under the shield are guaranteed to be protected from external EM interference. However, because the shield is fixed so tightly to the circuit board, if any of the components within the shield stop operating properly, an operator fixing the board must waste a lot of effort in destroying the welding to remove the shield, so as to inspect and replace the malfunctioning component(s).

Please refer to FIGS. 1-5. FIG. 1 is a top view of a circuit board 16, a dotted line representing a region to be covered by an EMI shield 10. FIG. 2 is a top view of the circuit board 16 after fastening a shield frame 12 of the EMI shield 10 to the circuit board 16. The shield frame 12 is welded to the circuit board 16. FIG. 3 is a perspective view of the shield frame 12 attached to the circuit board 16. FIG. 4 is a top view of the circuit board 16 after fastening a shield frame cover 14 onto the frame 12 of FIG. 2. FIG. 5 is a perspective view of FIG. 4.

An advantage of the complex EMI shield 10 is that it can completely cover dead space that simple-design EMI shields are unable to protect, achieving the objective of protecting shielded internal components from electromagnetic interference. Also, because the shield frame cover 14 can be freely removed, when the cover 14 is removed, a majority of the circuit board 16 is exposed. This allows for easier inspection and replacement of the internal components. However, the complex design has the following deficiencies: 1.) components in the immediate vicinity of the shield frame 12 are still not easily replaced; 2.) a structure of the shield frame 12 is weak, and when fastening the cover 14 to the frame 12, an external force must be applied in a direction of the frame 12 in order to securely fasten the cover 14, often causing deformation of the frame 12, and thus shifting the frame 12 away from the original position at which it would be welded to the circuit board 16, leaving a gap between the EMI shield 10 and the circuit board 16, thus lowering the ability of the shield 10 to protect the important internal components; 3.) because the shield frame 12 and the shield frame cover 14 are not formed together, the frame 12 and the cover 14 must be manufactured with very high levels of precision, insidiously increasing the manufacturing cost of the electronic product; and 4.) a thickness of the circuit board 16 when added to a height of the shield frame 12 causes the overall shielding structure to be very thick, to an extent that the structure thickness affects a configuration of the internal components of the electronic device.

Thus it is a difficult challenge to develop an easily fabricated EMI shield that is removable from a circuit board, and also has a secure and inexpensive architecture.

### SUMMARY OF INVENTION

Therefore, it is an objective of the claimed invention to provide a method for easily installing and removing an electromagnetic interference (EMI) shield from a circuit board.

Briefly, the claimed invention teaches a method of securely fastening an EMI shield to a circuit board. The circuit board has insertion holes and the EMI shield has fasteners corresponding to the holes of the circuit board. The method is to insert the fasteners of the EMI shield into the insertion holes of the circuit board so as to securely fasten the shield to the board.

It is an advantage of the claimed invention method that the EMI shield is easily fixed to the circuit board, and can be easily removed as the EMI shield is not attached by welding, or any other permanent means. Also, a manufacturing cost is relatively low.

These and other objectives of the claimed invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 is a top view of a circuit board according to the prior art.

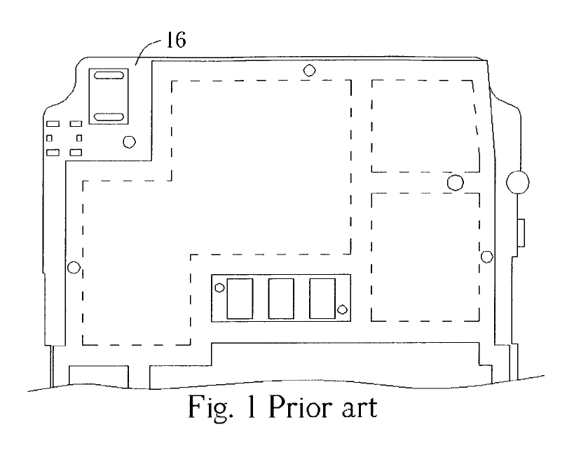

FIG. 2 is a top view of an electromagnetic interference (EMI) shield frame fastened to the circuit board, according to the prior art.

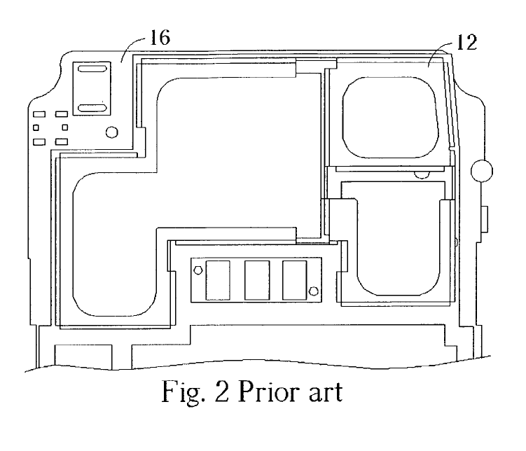

FIG. 3 is a perspective view of the prior art EMI shield frame and circuit board of FIG. 2.

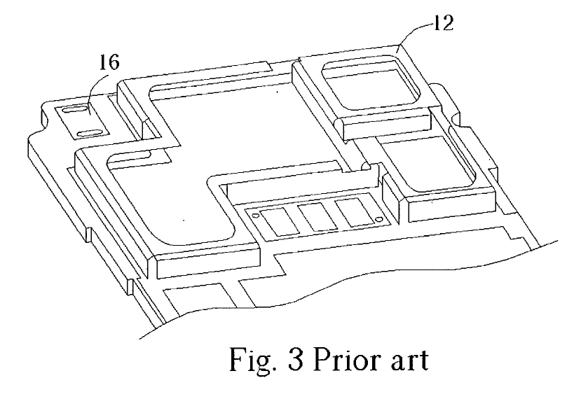

FIG. 4 is a top view of a shield cover covering the shield frame of FIG. 2, according to the prior art.

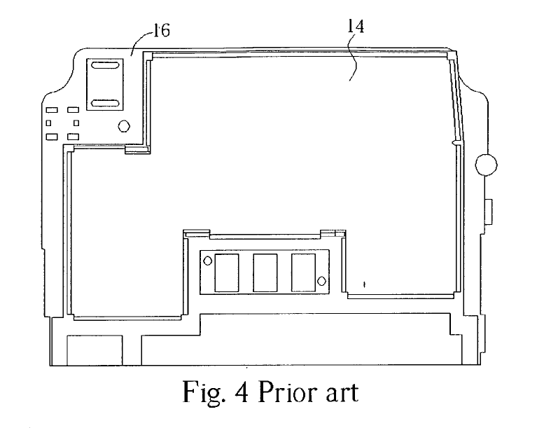

FIG. 5 is a perspective view of FIG. 4.

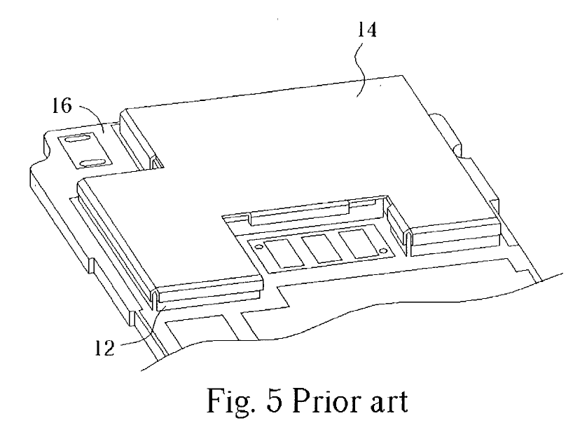

FIG. 6 is a top view of a circuit board of the present invention.

FIG. 7 is a perspective view of an EMI shield of the present invention.

FIG. 8 is a top view of the EMI shield fastened to the circuit board.

FIG. 9 is a perspective view of the EMI shield fastened to the circuit board.

FIG. 10 is an enlargement of a relevant portion of the circuit board and the EMI shield of FIG. 9 showing close fastening of the circuit board and the EMI shield.

FIG. 11 is a second embodiment of the present invention.

FIG. 12 is an end view of a plurality of fasteners after insertion into a plurality of insertion holes of the circuit board of the second embodiment of the present invention.

FIG. 13 is an end view of the tops of the plurality of fasteners of the EMI shield after being bent up under the circuit board, according to the second embodiment of the present invention.

### DETAILED DESCRIPTION

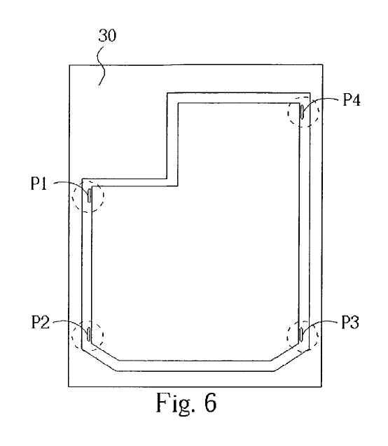

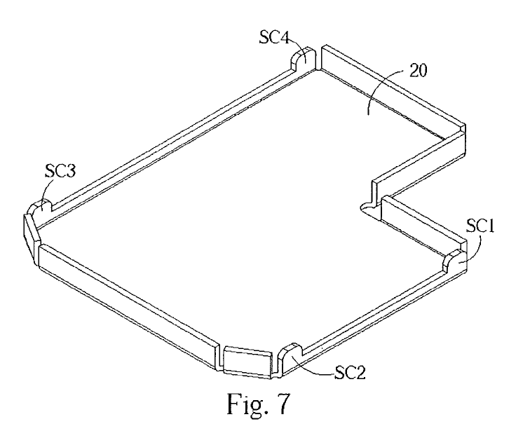

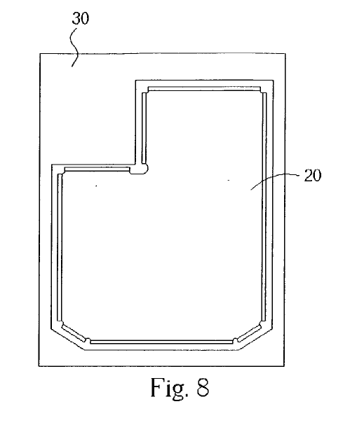

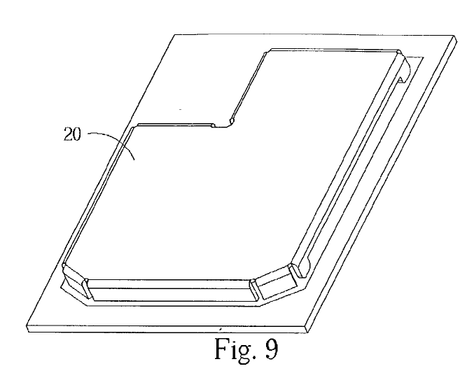

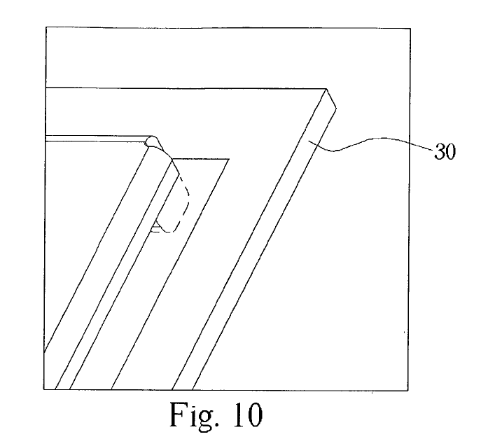

Please refer to FIGS. 6-11, which show the present invention method of securing an electromagnetic interference (EMI) shield 20 to a circuit board 30. FIG. 6 is a top view of the circuit board 30. The circuit board 30 is designed with a plurality of insertion holes p1, p2, p3, p4 (designated by dotted lines, also referred to in a group as p1-4) that are positioned at four corners of the circuit board 30. FIG. 7 is a perspective view of the EMI shield 20. The EMI shield 20 has a plurality of fasteners sc1, sc2, sc3, sc4 (also referred to in a group as sc1-4) corresponding to the plurality of insertion holes p1-4 at the four corners of the circuit board 30, and of length no greater than the thickness of the circuit board 30. FIG. 8 is a top view of the plurality of fasteners sc1-4 of the EMI shield 20 after insertion into the insertion holes p1-4 of the circuit board. FIG. 9 is a perspective view of FIG. 8. FIG. 10 is an enlarged view of a portion of FIG. 9 used to show that the circuit board 30 and the EMI shield 20 are closely fastened.

The present invention method of fastening the EMI shield 20 to the circuit board 30 is as follows: insert the plurality of fasteners sc1-4 of the EMI shield 20 into the corresponding plurality of insertion holes p1-4 of the circuit board 30, relying on a frictional force between the plurality of fasteners sc1-4 and the plurality of insertion holes p1-4 to cause the EMI shield 20 and the circuit board 30 to stick together, even if the circuit board 30 is turned over. Because the height of the fasteners sc1-4 does not exceed the thickness of the circuit board 30, after the fasteners sc1-4 are inserted into the insertion holes p1-4, the EMI shield 20 does not affect the structure of circuitry behind the circuit board 30.

When a user wants to remove the EMI shield 20 from the circuit board 30, because the EMI shield 20 was not welded to the circuit board 30 when being fastened, the user need only apply an external force to the back of the circuit board 30 to easily remove the EMI shield 20.

When an area of the circuit board 30 that needs to be covered is relatively large, the EMI shield 20 and the circuit board 30 can be designed with more fastener-insertion hole pairs to increase the strength of the fastening. Likewise, if the area to be covered is relatively small, fewer fastener-insertion hole pairs can be used to achieve close fastening of the EMI shield 20 and the circuit board 30.

Because the present invention method can be used for many different fabrication structures of electronic devices, the EMI shield 20 further comprises a plurality of fixed structures to allow for the fastening of the fixed structure of the EMI shield 20 and the circuit board 30 to various other structures of the electronic device in question. The plurality of fixed structures could be located at the top, or one side of the EMI shield 20, and be defined by the fabrication structure of components of the electronic device. The plurality of fixed structures could be of a fixed push-button structure, or another structure.

The EMI shield 20 of the method described above is indicated for temporarily fastening the shield 20 to the circuit board 30, and only used for testing important components that are on the circuit board 30 and within the EMI shield 20. When the EMI shield 20 must be more securely fastened to the circuit board 30, the following embodiment is provided.

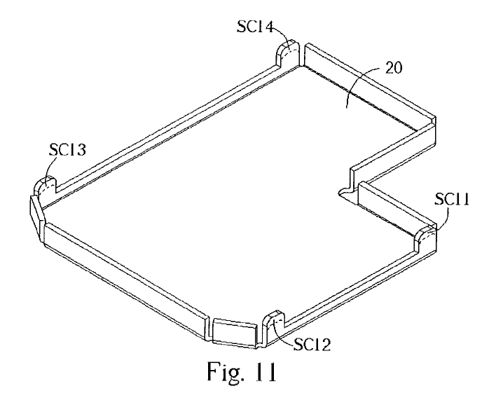

Please refer to FIG. 11, which is a second embodiment of the present invention method of fastening an EMI shield to a circuit board. Different from the EMI shield 20, described above, is that a plurality of fasteners sc11, sc12, sc13, sc14 of an EMI shield 40 has a height greater than the thickness of the circuit board 30 (dotted lines indicating the original height of the fasteners sc1-4).

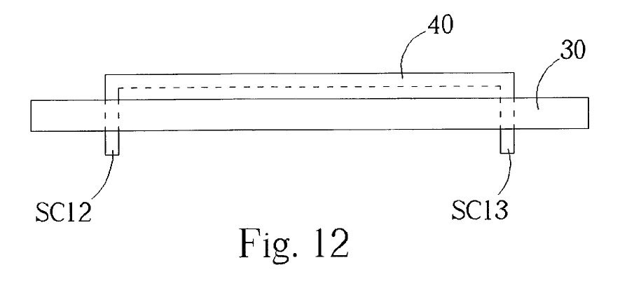

Please refer to FIG. 12 for a description of practical use. FIG. 12 shows an end view of the plurality of fasteners sc11-14 of the EMI shield 40 after being inserted into the plurality of insertion holes p1-4 of the circuit board 30. The ends of the fasteners sc12,13 protrude to the outside of the circuit board 30.

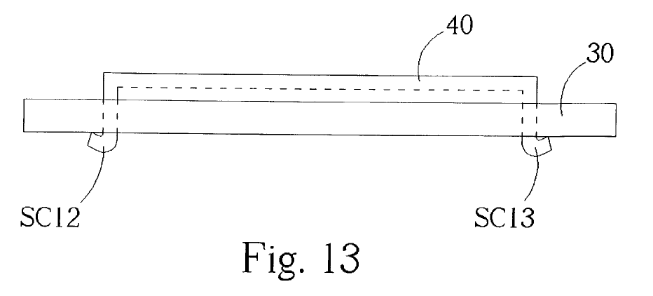

Please refer to FIG. 13, which shows an end view of the fasteners sc12,13 after being bent up under the circuit board 30. To remove the EMI shield 40 from the circuit board 30, the fasteners sc11-14 of the EMI shield 40 must first be bent back to their original shape, after which the EMI shield 40 can be pulled apart from the circuit board 30 without much effort.

In contrast with the prior art method, the present invention method allows for easy fixture of the EMI shield to the circuit board, achieves shielding of the important circuit components from EM interference, and because no welding is done during the fixing process, the EMI shield can be removed effortlessly from the circuit board. Furthermore, because of the use of a simple design, the manufacturing cost is low. The present invention can be used with any type of circuit board, such as printed circuit boards and other such boards.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fastening an electromagnetic interference (EMI) shield to a circuit board, the circuit board comprising a plurality of holes, the EMI shield comprising a plurality of fasteners corresponding to the plurality of holes of the circuit board, the method comprising:
inserting the plurality of fasteners into the plurality of holes to securely fasten the EMI shield to the circuit board.

2. The method of claim 1 wherein the circuit board is a printed circuit board.

3. The method of claim 1 wherein a height of the plurality of fasteners is no greater than a thickness of the circuit board.

4. The method of claim 3 wherein the plurality of fasteners is joined to the plurality of holes by intrusion.

5. The method of claim 1 wherein the EMI shield further comprises a plurality of fixed fittings used to fix the EMI shield to another structure.

6. The method of claim 5 wherein the plurality of fixed fittings is of a pushbutton structure.

7. The method of claim 1 wherein a height of the plurality of fasteners is greater than a thickness of the circuit board.

8. The method of claim 7 wherein after the plurality of fasteners is inserted into the plurality of holes, ends of the plurality of fasteners are bent under the circuit board.
